(19) United States
(12) Patent Application Publication
(10) Pub. No.: US 2026/0026237 A1
(43) Pub. Date: Jan. 22, 2026

(54) Display Module and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Xiaoxia Liu, Beijing (CN); Lian Xiang, Beijing (CN); Xiangdong Wei, Beijing (CN); Dianjie Hou, Beijing (CN); Tengfei Zheng, Beijing (CN)

(21) Appl. No.: 18/861,701

(22) PCT Filed: Aug. 14, 2024
(86) PCT No.: PCT/CN2024/112166

§ 371 Date: Oct. 30, 2024

(30) Foreign Application Priority Data
Sep. 27, 2023 (CN) 202311269791.3

(51) Int. Cl. H10K 59/80

(52) U.S. Cl. CPC H10K 59/872; H10K 59/8722

(57) ABSTRACT

A display module includes a display panel and a cover plate. The cover plate includes a first sub-portion and a second sub-portion. An orthographic projection of the first sub-portion on the display panel covers a display region of the display panel, and a boundary of the orthographic projection and a boundary of the display region are spaced apart. The second sub-portion is located on a side of the first sub-portion away from the display panel. A boundary of an orthographic projection of the second sub-portion on the display panel is located within the boundary of the orthographic projection of the first sub-portion on the display panel, and has a spacing from the boundary of the display region. A sidewall of the second sub-portion is provided with a concave-convex structure that extends along a circumferential direction of the second sub-portion and surrounds at least a portion of the second sub-portion.

### CROSS-REFERENCE TO RELATED APPLICATIONS

This application is the United States national phase of International Patent Application No. PCT/CN2024/112166, filed Aug. 14, 2024, and claims priority to Chinese Patent Application No. 202311269791.3, filed Sep. 27, 2023, the disclosures of which are hereby incorporated by reference in their entireties.

### BACKGOUND OF THE INVENTION

### Field of the Invention

The present disclosure relates to the field of display technologies, and in particular, to a display module and a display apparatus.

### Description of Related Art

Organic light-emitting diodes (OLEDs) have been widely used in the display field due to their advantages such as self-luminescence, low driving voltage, high luminous efficiency, fast response, and flexible display.

### SUMMARY OF THE INVENTION

In an aspect, a display module is provided. The display module includes a display panel and a cover plate. The display panel has a display region. The cover plate is located on a display side of the display panel, and the cover plate includes a first sub-portion and a second sub-portion. An orthographic projection of the first sub-portion on the display panel covers the display region of the display panel, and a boundary of the orthographic projection of the first sub-portion on the display panel and a boundary of the display region are spaced apart. The second sub-portion is located on a side of the first sub-portion away from the display panel. A boundary of an orthographic projection of the second sub-portion on the display panel is located within the boundary of the orthographic projection of the first sub-portion on the display panel, and the boundary of the orthographic projection of the second sub-portion on the display panel and the boundary of the display region are spaced apart. A sidewall of the second sub-portion is provided with a concave-convex structure, and the concave-convex structure extends along a circumferential direction of the second sub-portion and surrounds at least a portion of the second sub-portion.

In some embodiments, a surface roughness of the sidewall of the second sub-portion is less than or equal to 10 nm.

In some embodiments, the concave-convex structure includes a plurality of grooves arranged in a first direction, and the plurality of grooves are arranged continuously and/or at intervals, the first direction being perpendicular to the cover plate.

In some embodiments, a maximum depth of a groove is greater than a distance between two adjacent grooves.

In some embodiments, the concave-convex structure includes one groove and/or one protrusion.

In some embodiments, a distance between an end of the concave-convex structure away from the first sub-portion and the first sub-portion is greater than a half of a thickness of the second sub-portion.

In some embodiments, a distance between an end of the concave-convex structure close to the first sub-portion and the first sub-portion is less than or equal to a half of the thickness of the second sub-portion.

In some embodiments, an edge of a surface of the second sub-portion away from the first sub-portion is provided with a chamfer; and a ratio of a distance between an end of the concave-convex structure away from the first sub-portion and a surface of the second sub-portion away from the first sub-portion to a thickness of the second sub-portion is in a range of 0.05 to 0.2.

In some embodiments, an orthographic projection of the sidewall of the second sub-portion on the display panel is substantially in a shape of a circle.

In some embodiments, the groove extends along a circumferential direction of the second sub-portion; two extending ends of the groove are a first end and a second end; and the second end is located on a side of the first end close to the first sub-portion to form a first thread. The groove surrounds the second sub-portion at least three turns.

In some embodiments, a boundary line of an orthographic projection of the concave-convex structure on a reference plane includes a curved line and a straight line, the reference plane being perpendicular to the cover plate and perpendicular to a boundary of the second sub-portion.

In some embodiments, the concave-convex structure of the second sub-portion of the cover plate includes a groove, and a ratio of a maximum depth of the groove to a distance between a boundary of the display region of the display panel and a boundary of an orthographic projection of the sidewall of the second sub-portion on the display panel is in a range of 0.05 to 1.

In some embodiments, a distance between a boundary of the display region of the display panel and a boundary of an orthographic projection of the sidewall of the second sub-portion on the display panel is in a range of 150 μm to 300 μm.

In another aspect, a display apparatus is provided. The display apparatus includes the display module as described in any of the above embodiments and a middle frame. The middle frame is located on the side of the first sub-portion of the cover plate away from the display panel; the middle frame extends along the circumferential direction of the second sub-portion of the cover plate and surrounds the first sub-portion; and the middle frame wraps at least a portion of the concave-convex structure of the second sub-portion.

In some embodiments, a second end is located on a side of a first end close to the first sub-portion to form a first thread, a sidewall of the middle frame close to the second sub-portion is provided with a second thread, and the first thread and the second thread are screwed together.

In some embodiments, the middle frame and the cover plate enclose an accommodation cavity; the display apparatus further comprises a bonding block, the bonding block is located inside the accommodation cavity, and the middle frame and the cover plate are bonded through the bonding block.

In some embodiments, the display apparatus further includes a light-shielding layer. The light-shielding layer is located between the display panel and the cover plate and surrounding the display region of the display panel. An orthographic projection of the light-shielding layer on the display panel at least partially overlaps with an orthographic projection, on the display panel, of a portion of the first sub-portion exceeding the second sub-portion.

In some embodiments, the orthographic projection of the light-shielding layer on the display panel partially overlaps with the orthographic projection of the second sub-portion on the display panel.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a circular display apparatus, in accordance with some embodiments;

FIG. 3 is a structural diagram of another circular display apparatus, in accordance with some embodiments;

FIG. 4 is a structural diagram of a rectangular display apparatus, in accordance with some embodiments;

FIG. 5 is a sectional view taken along the section line C-C in FIG. 2;

FIG. 6 is a partial enlarged view of the region D in FIG. 5;

FIG. 7 is another partial enlarged view of the region D in FIG. 5;

FIG. 8 is yet another partial enlarged view of the region D in FIG. 5;

FIG. 9 is yet another partial enlarged view of the region D in FIG. 5;

FIG. 10 is yet another partial enlarged view of the region D in FIG. 5;

FIG. 11 is yet another partial enlarged view of the region D in FIG. 5;

FIG. 12 is yet another partial enlarged view of the region D in FIG. 5;

FIG. 13 is yet another partial enlarged view of the region D in FIG. 5;

FIG. 14 is a diagram showing a structure of a wave, in accordance with some embodiments;

FIG. 15 is a diagram showing a structure of a small wave, in accordance with some embodiments;

FIG. 16 is a diagram showing a structure of a middle frame and a cover plate connected through threads, in accordance with some embodiments;

FIG. 17 is a diagram showing a structure of a middle frame and a cover plate connected through a bonding block, in accordance with some embodiments; and

FIG. 18 is a flow diagram of a method of manufacturing a cover plate, in accordance with some embodiments.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above term do not necessarily refer to the same embodiment(s) or example(s). In addition, specific features, structures, materials or characteristics may be included in any one or more embodiments or examples in any suitable manner.

Hereinafter, the terms “first” and “second” are only used for descriptive purposes, and are not to be construed as indicating or implying relative importance or implicitly indicating the number of indicated technical features. Thus, features defined with the terms such as “first” and “second” may explicitly or implicitly include one or more of the features. In the description of the embodiments of the present disclosure, term “a plurality of” or “the plurality of” means two or more unless otherwise specified.

In the description of some embodiments, terms such as “coupled” and “connected” and their derivatives may be used. For example, the term “connected” may be used in the description of some embodiments to indicate that two or more components are in direct physical or electrical contact with each other. As another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if”, depending on the context, is optionally construed as “when” or “in a case where” or “in response to determining that” or “in response to detecting”. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event],” depending on the context.

The use of “applicable to” or “configured to” herein means an open and inclusive expression, which does not exclude devices that are applicable to or configured to perform additional tasks or steps.

Additionally, the use of the phrase “based on” is meant to be open and inclusive, since a process, step, calculation or other action that is “based on” one or more of the stated conditions or values may, in practice, be based on additional conditions or value beyond those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the drawings, thicknesses of layers and sizes of regions are enlarged for clarity. Thus, variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

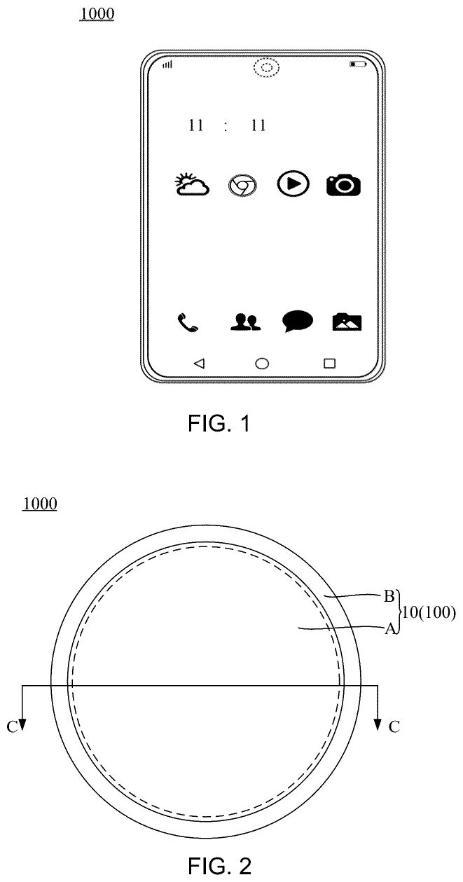

Some embodiments of the present disclosure provide a display apparatus 1000. As shown in FIG. 1, the display apparatus 1000 may be any apparatus that displays an image whether in motion (e.g., a video) or stationary (e.g., a still image), and whether textual or graphical. For example, the display apparatus 1000 may be any product or component having a display function, such as a television, a notebook computer, a tablet computer, a mobile phone, a personal digital assistant (PDA), a navigator, a wearable device, an augmented reality (AR) device, or a virtual reality (VR) device.

The display apparatus 1000 may be a liquid crystal display (LCD) display apparatus, an organic light-emitting diode display apparatus, a quantum dot light-emitting diode (QLED) display apparatus, an active-matrix organic light-emitting diode (AMOLED) display apparatus, a micro light-emitting diode (Micro LED), or a mini light-emitting diode (Mini LED). Micro LED refers to an LED whose LED chip size is less than 50 μm, and Mini LED refers to an LED whose LED chip size is in a range of 50 μm to 200 μm.

Some embodiments of the present disclosure will be schematically described below by taking an example in which the display apparatus 1000 is an organic light-emitting diode display apparatus 1000. However, the implementations of the present disclosure are not limited thereto, and any other display apparatus 1000 may also be considered as long as the same technical concept is applied.

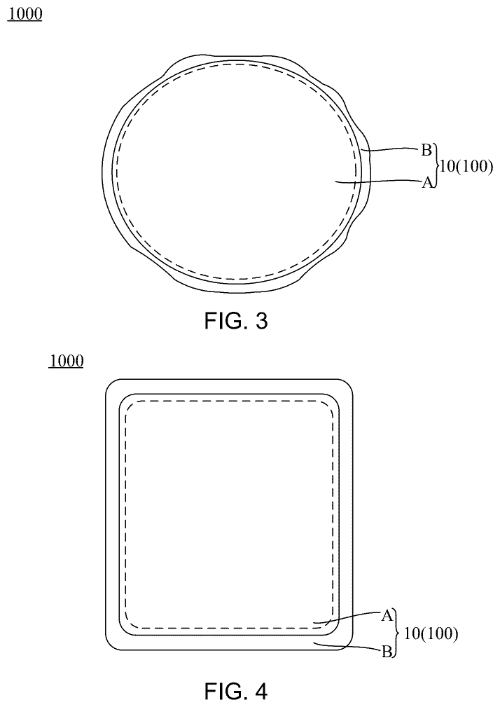

For example, as shown in FIGS. 2 to 4, when the display apparatus 1000 is a wearable device, the display apparatus 1000 may be a round watch as shown in FIGS. 2 and 3 or a square watch as shown in FIG. 4.

Some embodiments of the present disclosure will be schematically described below by taking an example in which the display apparatus 1000 is a round watch. However, the implementations of the present disclosure are not limited thereto, and any other display apparatus 1000 may also be considered as long as the same technical concept is applied.

As shown in FIGS. 2 to 5, the display apparatus 1000 includes a display module 100. The display module 100 includes a display panel 10 and a cover plate 20.

As shown in FIG. 2, the display panel 10 includes a display region A (a region enclosed by the dotted line in FIG. 2) and a peripheral region B (a region outside the region enclosed by the dotted line in FIG. 2) arranged on at least one side of the display region A. FIGS. 2 to 4 illustrate examples that the peripheral region B is arranged around the display region A.

In some examples, as shown in FIGS. 2 and 3, the display region A is substantially in a shape of a circle.

Herein, “substantially in a shape of a circle or ellipse” means in a shape of a circle or ellipse as a whole, but is not limited to a shape of a standard circle or ellipse. That is, the “circle or ellipse” here includes not only a standard circle or ellipse but also a shape similar to a circle or ellipse.

The display region A is a region where an image is displayed, and is configured to be provided therein with a plurality of pixel units. The peripheral region B is a region where no image is displayed, and is configured to be provided therein with display driver circuits such as a gate driver circuit and a source driver circuit.

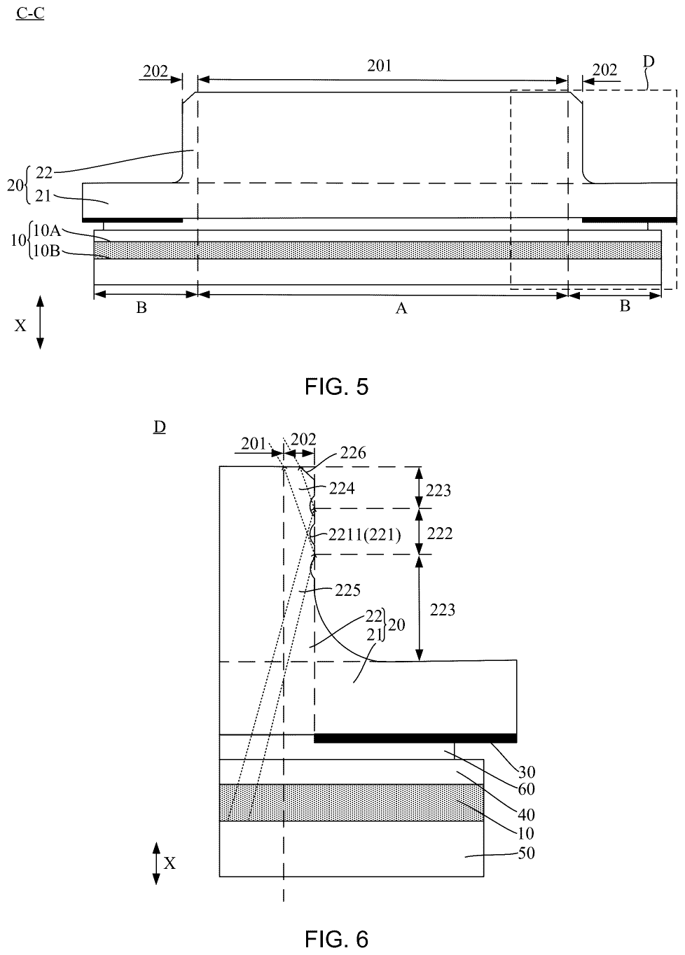

As shown in FIG. 5, the display panel 10 has a display side 10A and a non-display side 10B that are opposite to each other. It will be noted that the display side 10A refers to a side of the display panel 10 where an image is displayed (an upper side of the display panel 10 in FIG. 5), and the non-display side 10B refers to another surface opposite to the display side 10A (a lower side of the display panel 10 in FIG. 5).

As shown in FIG. 5, the cover plate 20 is located on the display side 10A of the display panel 10. The cover plate 20 includes a first sub-portion 21 and a second sub-portion 22.

An orthographic projection of the first sub-portion 21 on the display panel 10 covers the display region A, and a boundary of the orthographic projection and a boundary of the display region A are spaced apart. The second sub-portion 22 is located on a side of the first sub-portion 21 away from the display panel 10. A boundary of an orthographic projection of the second sub-portion 22 on the display panel 10 is located within the boundary of the orthographic projection of the first sub-portion 21 on the display panel 10, and has a spacing from the boundary of the display region A.

In this way, the cover plate 20 may shield the display panel 10, thereby reducing the risk of the display panel 10 being scratched, and in turn increasing the service life of the display panel 10.

For example, as shown in FIG. 2, a boundary of an orthographic projection of the cover plate 20 on the display panel 10 (the boundary of the orthographic projection of the first sub-portion 21 on the display panel 10) is substantially in a shape of a circle; alternatively, for example, as shown in FIG. 4, the boundary of the orthographic projection of the cover plate 20 on the display panel 10 is substantially in a shape of a square; alternatively, for example, as shown in FIG. 3, the boundary of the orthographic projection of the cover plate 20 on the display panel 10 has an irregular shape. The embodiments of the present disclosure do not list it one by one here.

For example, a material of the cover plate 20 includes sapphire or glass.

In some embodiments, as shown in FIG. 5, a distance between the boundary of the display region A and a boundary of an orthographic projection of a sidewall of the second sub-portion 22 on the display panel 10 is in a range of 150 μm to 300 μm.

As shown in FIG. 5, the second sub-portion 22 includes: a first surface and a second surface that are opposite to each other, and the sidewall between the first surface and the second surface. The first surface is a surface close to the display panel 10, and the second surface is a surface far away from the display panel 10.

For example, the distance between the boundary of the display region A and the boundary of the orthographic projection of the sidewall of the second sub-portion 22 on the display panel 10 is 150 μm, 153 μm, 155 μm, 160 μm, 180 μm, 200 μm, 240 μm, 270 μm, 290 μm or 300 μm, which will not be listed one by one in the embodiments of the present disclosure.

In this way, the display module 100 may have a narrower bezel, which is beneficial to achieving the purpose of a narrow bezel of the display apparatus 1000.

In some embodiments, as shown in FIG. 5, a surface roughness of the sidewall of the second sub-portion 22 is less than or equal to 10 nm. For example, the surface roughness of the sidewall of the second sub-portion 22 is 10 nm, 8 nm, 7 nm, 5 nm, 4 nm or 1 nm, which will not be listed one by one in the embodiments of the present disclosure.

In this way, the sidewall of the second sub-portion 22 is relatively smooth. That is, the sidewall of the second sub-portion 22 has good quality, which may improve the mechanical properties of the sidewall of the second sub-portion 22, and in turn improve the mechanical properties (such as anti-drop performance, anti-extrusion performance or waterproof performance) of the display apparatus 1000.

In some embodiments, as shown in FIG. 5, the first sub-portion 21 has a first region 201 and a second region 202 surrounding the first region 201. An orthographic projection of the first region 201 on the display panel 10 substantially coincides with the display region A.

In the related art, a part of light emitted from the display region of the display panel enters the second region, is reflected by the sidewall of the second sub-portion, and then exits from the second region to the outside. Generally, when a user views the display apparatus, a distance between the human eye and the display apparatus is in a range of 30 cm to 40 cm. That is, a distance between the human eye and the cover plate 20 is in a range of 30 cm to 40 cm. The distance from the human eye to the cover plate is much greater than the distance between the boundary of the orthographic projection of the sidewall of the second sub-portion on the display panel and the boundary of the display region. Therefore, it will be considered that light rays emitted from the second region to the human eye are substantially parallel. Thus, when the user looks at the display appparatus obliquely at a specific angle of, e.g., 30° (an angle between a line of sight of the user and a normal line of a surface, away from the display panel, of the cover plate is 30°), light may be transmitted from the second region to the human eye, causing the user to view a display image of the second sub-portion located in the second region. As a result, the display apparatus has a “display ghosting” problem.

In order to solve the above problems, as shown in FIG. 6, in some embodiments of the present disclosure, the sidewall of the second sub-portion 22 of the cover plate 20 is provded with a concave-convex structure 221. The concave-convex structure 221 extends along a circumferential direction of the second sub-portion 22 and surrounds at least a portion of the second sub-portion 22.

In this way, at least part of the light transmitted to the human eye in the second region 202 may be reflected by the concave-convex structure 221 to the first region 201, and then exits from the first region 201. Therefore, the cover plate 20 provided in some embodiments of the present disclosure may mitigate the problem of light being transmitted from the second region 202 to the human eye, and reduce the risk of the “display ghosting” problem of the display apparatus 1000 caused by light being transmitted to the human eye.

The light in the second region 202 that is transmitted to the human eye includes incident light and reflected light. It will be noted that the incident light refers to light that enters the second region 202 from the display region A, and the reflected light refers to light that is reflected by the sidewall of the second sub-portion 22.

In some examples, the concave-convex structure 221 may reflect the incident light in the second region 202 to the first region 201 and then the light exits from the first region 201.

In some other examples, the concave-convex structure 221 may reflect the reflected light in the second region 202 to the first region 201 and then the light exits from the first region 201.

In yet some other examples, the concave-convex structure 221 reflects the incident light in the second region 202 to the first region 201 and then the light exits from the first region 201; and the concave-convex structure 221 may also reflect the reflected light in the second region 202 to the first region 201 and then the light exits from the first region 201.

In some embodiments, as shown in FIGS. 6 to 12, the concave-convex structure 221 includes at least one groove 2211. The at least one groove 2211 reflects at least part of the light transmitted to the human eye to the first region 201, and then the at least part of the light exits from the first region 201.

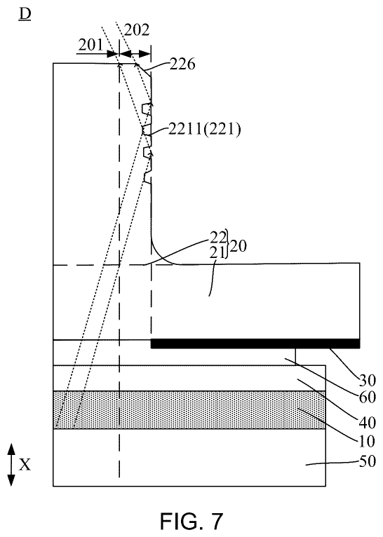

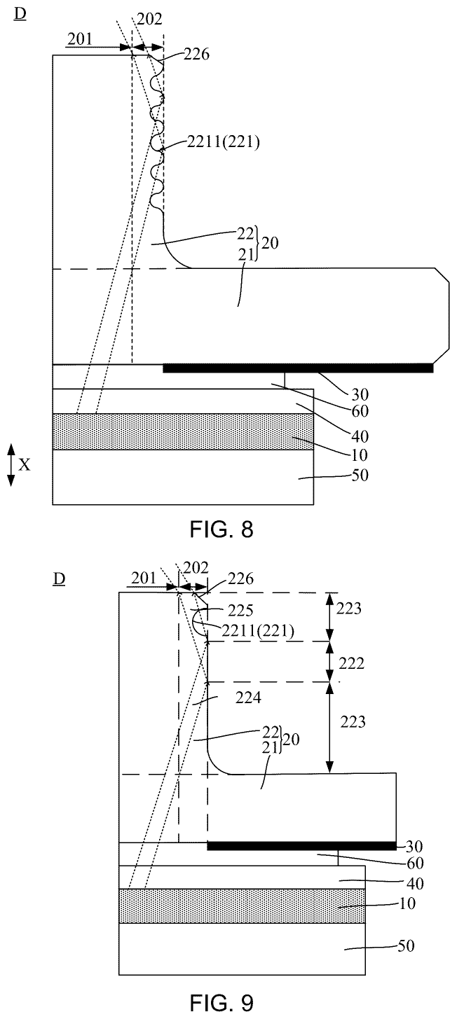

In some examples, as shown in FIGS. 6 to 8, the concave-convex structure 221 includes a plurality of grooves 2211 arranged in the first direction X. For example, as shown in FIGS. 6 and 7, the plurality of grooves 2211 are arranged at intervals. Alternatively, for example, as shown in FIG. 8, the plurality of grooves 2211 are arranged consecutively. Alternatively, for another example, some of the plurality of grooves 2211 are arranged at intervals, and some of the plurality of grooves 2211 are arranged consecutively.

In some other examples, as shown in FIGS. 9 to 12, the concave-convex structure 221 includes one groove 2211.

In some other embodiments, as shown in FIG. 13, the concave-convex structure 221 includes at least one protrusion 2212. The at least one protrusion 2212 reflects at least part of the light transmitted to the human eye to the first region 201, and then the at least part of the light exits from the first region 201.

In some examples, the concave-convex structure 221 includes a plurality of protrusions 2212 arranged in the first direction X. For example, the plurality of protrusions 2212 are arranged at intervals. Alternatively, for example, the plurality of protrusions 2212 are arranged consecutively. Alternatively, for another example, some of the plurality of protrusions 2212 are arranged at intervals, and some of the plurality of protrusions 2212 are arranged consecutively.

In some other examples, as shown in FIG. 13, the concave-convex structure 221 includes one protrusion 2212.

In yet some other embodiments, the concave-convex structure 221 includes at least one protrusion 2212 and at least one groove 2211. The at least one protrusion 2212 and the at least one groove 2211 reflect at least part of the light transmitted to the human eye to the first region 201, and then the at least part of the light exits from a surface, away from the first sub-portion 21, of the second sub-portion 22 located in the first region 201.

In some examples, the concave-convex structure 221 includes a plurality of grooves 2211 and one protrusion 2212.

In some other examples, the concave-convex structure 221 includes a plurality of grooves 2211 and a plurality of protrusions 2212.

In yet some other examples, the concave-convex structure 221 includes one groove 2211 and a plurality of protrusions 2212.

In yet some other examples, the concave-convex structure 221 includes one groove 2211 and one protrusion 2212.

In some embodiments, as shown in FIG. 6, a boundary line of an orthographic projection of the concave-convex structure 221 on a reference surface includes a curved line. The reference plane is perpendicular to the cover plate 20 and perpendicular to a boundary of the second sub-portion 22. It will be understood that when the boundary of the second sub-portion 22 is a straight line, the reference plane is perpendicular to the straight line. When the boundary of the second sub-portion 22 is a curved line, the reference plane is perpendicular to a normal line of the curved line.

In some other embodiments, as shown in FIG. 7, the boundary line of the orthographic projection of the concave-convex structure 221 on the reference surface includes a straight line.

In yet some other embodiments, the boundary line of the orthographic projection of the concave-convex structure 221 on the reference surface includes a straight line and a curved line.

In some embodiments, as shown in FIG. 6, an angle between the light emitted from the display region A and the display panel 10 is in a range of 30° to 90°. That is, a light-exiting angle of the display panel 10 is in a range of 30° to 150°.

For example, the light-exiting angle of the display panel 10 is 30°, 35°, 45°, 50°, 58°, 62°, 70°, 75°, 79°, 80°, 82°, 85°, 89° or 90°, which will not be listed one by one in the embodiments of the present disclosure.

In this way, as shown in FIG. 6, the light in the second region 202 that is transmitted to the human eye is reflected on an upper middle portion of the sidewall of the second sub-portion 22. That is, the sidewall of the second sub-portion 22 includes a reflective portion 222 and a non-reflective portion 223. For example, a spacing between an end of the reflective portion 222 close to the first sub-portion 21 and the first sub-portion 21 is greater than or equal to a half of a thickness of the second sub-portion 22. For example, the spacing between an end of the reflective portion 222 close to the first sub-portion 21 and the first sub-portion 21 is equal to a half of the thickness of the second sub-portion 22. The reflective portion 222 refers to a portion of the sidewall of the second sub-portion 22 that reflects the incident light, and the non-reflective portion 223 refers to a portion of the sidewall of the second sub-portion 22 that does not reflect the incident light.

As shown in FIG. 6, when the spacing between an end of the reflective portion 222 close to the first sub-portion 21 and the first sub-portion 21 is equal to a half of the thickness of the second sub-portion 22, a distance between an end of the concave-convex structure 221 away from the first sub-portion 21 and the first sub-portion 21 is greater than a half of the thickness of the second sub-portion 22.

In this way, when the concave-convex structure 221 includes the groove 2211, no matter how deep the groove 2211 is, at least part of the light transmitted to the human eye in the second region 202 may be reflected by the groove 2211 to the first region 201 and then exits from the first region 201, thereby reducing the risk of the “display ghosting” problem of the display apparatus 1000 caused by light being transmitted to the human eye.

When the concave-convex structure 221 includes the protrusion 2212, the light transmitted to the human eye may be incident onto the protrusion 2212, and at least part of the light transmitted to the human eye in the second region 202 may be reflected by the protrusion 2212 to the first region 201 and then exits from the first region 201, thereby reducing the risk of the “display ghosting” problem of the display apparatus 1000 caused by light being transmitted to the human eye.

As shown in FIG. 6, on the basis that the distance between an end of the concave-convex structure 221 away from the first sub-portion 21 and the first sub-portion 21 is greater than a half of the thickness of the second sub-portion 22, a distance between an end of the concave-convex structure 221 close to the first sub-portion 21 and the first sub-portion 21 is less than or equal to a half of the thickness of the second sub-portion 22.

In this way, most of the light transmitted to the human eye may be reflected by the concave-convex structure 221 to the first region 201 and then exits from the first region 201, thereby reducing the risk of the “display ghosting” problem of the display apparatus 1000 caused by light being transmitted to the human eye.

In some embodiments, as shown in FIG. 6, an edge of the surface of the second sub-portion 22 away from the first sub-portion 21 is provided with a chamfer 226.

In this way, the chamfer 226 may remove burrs on the edge of the surface of the second sub-portion 22 away from the first sub-portion 21.

In addition, the chamfer 226 may reflect light incident on an upper portion of the sidewall of the second sub-portion 22 to the first region 201 and then the light exits from the first region 201, thereby reducing the risk of the “display ghosting” problem of the display apparatus 1000 caused by light being transmitted to the human eye. For example, a ratio of a spacing between an end of the upper portion of the sidewall of the second sub-portion 22 close to the first sub-portion 21 and the surface of the second sub-portion 22 away from the first sub-portion 21 to the thickness of the second sub-portion 22 is 0.2. That is, the ratio of the spacing between an end of the reflective portion 222 away from the first sub-portion and the surface of the second sub-portion 22 away from the first sub-portion 21 to the thickness of the second sub-portion 22 is 0.2.

In some embodiments, as shown in FIG. 6, on the basis that the edge of the surface of the second sub-portion 22 away from the first sub-portion 21 is provided with the chamfer 226, a ratio of a distance between the end of the concave-convex structure 221 away from the first sub-portion 21 and the surface of the second sub-portion 22 away from the first sub-portion 21 to the thickness of the second sub-portion 22 is in a range of 0.05 to 0.2.

For example, the ratio of the distance between the end of the concave-convex structure 221 away from the first sub-portion 21 and the surface of the second sub-portion 22 away from the first sub-portion 21 to the thickness of the second sub-portion 22 is 0.05, 0.06, 0.07, 0.08, 0.09, 0.12, 0.14, 0.15, 0.17, 0.19 or 0.2, which will not be listed one by one in the embodiments of the present disclosure.

In this way, there is no concave-convex structure 221 on the upper portion of the sidewall of the second sub-portion 22, and the mechanical properties of the sidewall of the second sub-portion 22 may be improved.

Some embodiments of the present disclosure will be schematically described below by taking an example in which the concave-convex structure 221 includes at least one groove 2211. However, the embodiments of the present disclosure are not limited thereto, and any other concave-convex structure 221 may also be considered as long as the same technical concept is applied.

In some embodiments, as shown in FIG. 6, the cover plate 20 includes an incident region 224 and a reflective region 225. The incident region 224 refers to a region created by the incident light included in the light transmitted to the human eye. The reflective region 225 is a region created by the reflected light included in the light transmitted to the human eye. The incident region 224 and the reflective region 225 have an overlapping portion.

In some examples, as shown in FIG. 6, an orthographic projection of the at least one groove 2211 on the reference plane partially overlaps with an orthographic projection of the incident region 224 on the reference plane.

In this way, the at least one groove 2211 may reflect at least part of the incident light to the first region 201, and then the at least part of the incident light exits from the first region 201, thereby reducing the risk of the “display ghosting” problem of the display apparatus 1000 caused by light being transmitted to the human eye.

In some other examples, as shown in FIG. 6, the orthographic projection of the at least one groove 2211 on the reference plane partially overlaps with an orthographic projection of the reflective region 225 on the reference plane.

In this way, the at least one groove 2211 may reflect at least part of the reflected light to the first region 201, and then the at least part of the reflected light exits from the first region 201, thereby reducing the risk of the “display ghosting” problem of the display apparatus 1000 caused by light being transmitted to the human eye.

In yet some other examples, as shown in FIG. 6, the orthographic projection of the at least one groove 2211 on the reference plane partially overlaps with the orthographic projection of the incident region 224 on the reference plane, and partially overlaps with the orthographic projection of the reflective region 225 on the reference plane.

In this way, the at least one groove 2211 may reflect at least part of the incident light to the first region 201 and then the at least part of the incident light exits from the first region 201, and the at least one groove 2211 may also reflect at least part of the reflected light to the first region 201 and then the at least part of the reflected light exits from the first region 201, thereby reducing the risk of the “display ghosting” problem of the display apparatus 1000 caused by light being transmitted to the human eye.

In some embodiments, as shown in FIG. 6, a ratio of a maximum depth of the groove 2211 to the distance between the boundary of the display region A and the boundary of the orthographic projection of the sidewall of the second sub-portion 22 on the display panel 10 is in a range of 0.05 to 1.

For example, the ratio of the maximum depth of the groove 2211 to the distance between the boundary of the display region A and the boundary of the orthographic projection of the sidewall of the second sub-portion 22 on the display panel 10 is 0.05, 0.1, 0.4, 0.7, 0.9 or 1, which will not be listed one by one in the embodiments of the present disclosure.

In this way, most of the light transmitted to the human eye may be reflected by the groove(s) 2211 to the first region 201 and then exits from the first region 201. Thus, it may be possible to reduce the risk of the “display ghosting” problem of the display apparatus 1000 caused by light being transmitted to the human eye.

In addition, the groove(s) are only located in the second region 202, so that the groove(s) will not affect the normal display of the display region A.

In some embodiments, when the concave-convex structure 221 includes a plurality of grooves 2211, a maximum depth of a groove 2211 may be less than depths of two adjacent grooves 2211.

In this way, when the plurality of grooves 2211 are processed, the processing efficiency of the grooves 2211 may be improved.

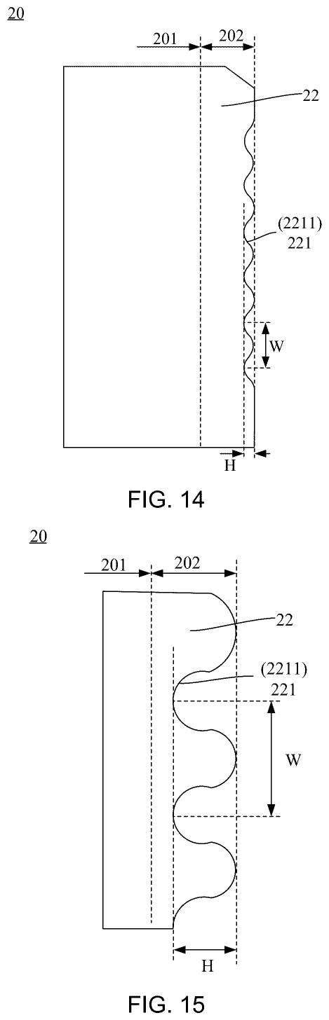

In some embodiments, as shown in FIGS. 14 and 15, when the concave-convex structure 221 includes a plurality of grooves 2211 consecutively arranged in the first direction X, a boundary line of an orthographic projection of the plurality of grooves 2211 on the reference surface is in a shape of a wave.

In some examples, as shown in FIG. 14, a ratio of a wavelength H to a wave height W is greater than or equal to 10.

For example, the ratio of the wavelength H to the wave height W is 10, 12, 15, 18, 20 or 30, which will not be listed one by one in the embodiments of the present disclosure.

For example, when the wave height W is 20 μm, the wavelength H may be 200 μm.

In some other examples, as shown in FIG. 15, the ratio of the wavelength H to the wave height W is in a range of 2 to 5.

For example, the ratio of the wavelength H to the wave height W is 2, 2.5, 3, 3.3, 4 or 5, which will not be listed one by one in the embodiments of the present disclosure.

For example, when the wave height W is 20 μm, the wavelength H may be in a range of 60 μm to 80 μm.

For example, the wavelength H may be 60 μm, 62 μm, 65 μm, 68 μm, 70 μm, 74 μm, 78 μm, or 80 μm, which will not be listed one by one in the embodiments of the present disclosure.

In some embodiments, as shown in FIGS. 9 to 12, the concave-convex structure 221 includes one groove 2211.

In some examples, as shown in FIG. 9, the orthographic projection of the groove 2211 on the reference plane partially overlaps with an orthographic projection, on the reference plane, of a portion of the reflective region 225 that does not overlap with the incident region 224. That is, the groove 2211 is located on a side of the reflective portion 222 away from the first sub-portion 21.

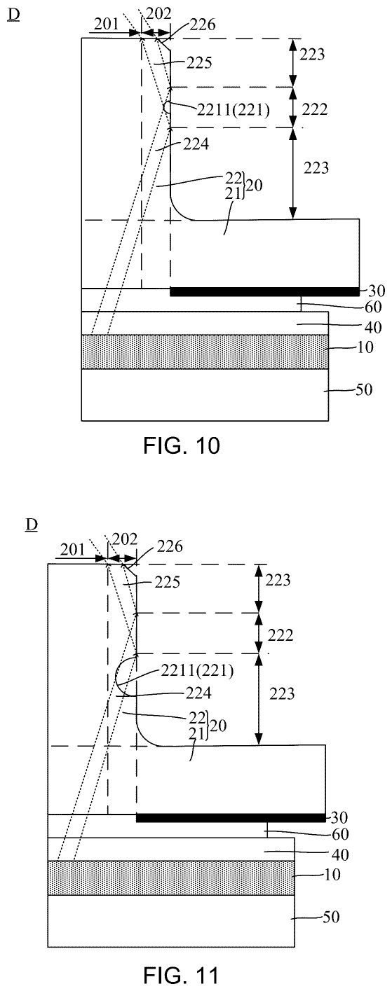

In some other examples, as shown in FIG. 10, the orthographic projection of the groove 2211 on the reference plane at least partially overlaps with an orthographic projection of an overlapping portion of the incident region 224 and the reflective region 225 on the reference plane. That is, the groove 2211 is only located on the reflective portion 222.

In this way, the maximum depth of the groove 2211 may be small, and less material is removed from the second sub-portion 22. Thus, the mechanical strength of the second sub-portion 22 may be improved.

In yet some other examples, as shown in FIG. 11, the orthographic projection of the groove 2211 on the reference plane partially overlaps with an orthographic projection, on the reference plane, of a portion of the incident region 224 that does not overlap with the reflective region 225. That is, the groove 2211 is located on a side of the reflective portion 222 close to the first sub-portion 21.

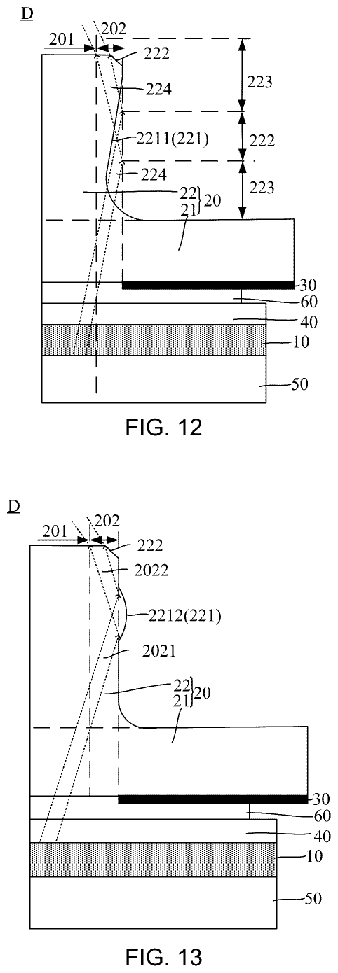

In some other examples, as shown in FIG. 12, the orthographic projection, on the reference plane, of the groove 2211 overlaps with the orthographic projections, on the reference plane, of the portion of the reflective region 225 that does not overlap with the incident region 224, the overlapping portion of the incident region 224 and the reflective region 225, and the portion of the incident region 224 that does not overlap with the reflective region 225. That is, the groove 2211 is located on both the reflective portion 222 and the non-reflective portion 223.

In some embodiments, as shown in FIG. 6, the distance between the boundary of the display region A and the boundary of the orthographic projection of the sidewall of the second sub-portion 22 on the display panel 10 is 200 μm, and the maximum depth of the groove 2211 may be in a range of 10 μm to 200 μm.

For example, the maximum depth of the groove 2211 may be 10 μm, 15 μm, 20 μm, 30 μm, 50 μm, 80 μm, 100 μm, 110 μm, 150 μm, 180 μm or 200 μm, which will not be listed one by one in the embodiments of the present disclosure.

In some examples, during the process of manufacturing the display module 100, the display panel 10 and the cover plate 20 may have an attaching tolerance (e.g., the attaching tolerance is ±150 μm). The maximum depth of the groove 2211 may be in a range of 10 μm to 50 μm.

For example, the maximum depth of the groove 2211 may be 10 μm, 12 μm, 15 μm, 17 μm, 18 μm, 20 μm, 25 μm, 30 μm, 38 μm, 40 μm or 50 μm, which will not be listed one by one in the embodiments of the present disclosure.

In this way, it may be possible to mitigate the problem that the attaching tolerance causes the groove 2211 to affect the normal display of the display region A.

In some examples, during the process of fabricating the groove 2211, the groove 2211 has a sidewall shape tolerance (e.g., the sidewall shape tolerance is ±25 μm). The maximum depth of the groove 2211 may be in a range of 10 μm to 175 μm.

For example, the maximum depth of the groove 2211 may be 10 μm, 20 μm, 30 μm, 40 μm, 50 μm, 60 μm, 70 μm, 100 μm, 150 μm, 170 μm or 175 μm, which will not be listed one by one in the embodiments of the present disclosure.

In this way, it may be possible to mitigate the problem that the sidewall shape tolerance causes the groove 2211 to affect the normal display of the display region A.

In some examples, the maximum depth of the groove 2211 may be in a range of 10 μm to 25 μm.

For example, the maximum depth of the groove 2211 may be 10 μm, 12 μm, 13 μm, 15 μm, 16 μm, 17 μm, 19 μm, 20 μm, 22 μm, 24 μm or 25 μm, which will not be listed one by one in the embodiments of the present disclosure.

In this way, it may be possible to mitigate the problem that the attaching tolerance and the sidewall shape tolerance causes the groove 2211 to be located in the first region 201, and in turn reduce the risk of the groove 2211 affecting the normal display of the display region A.

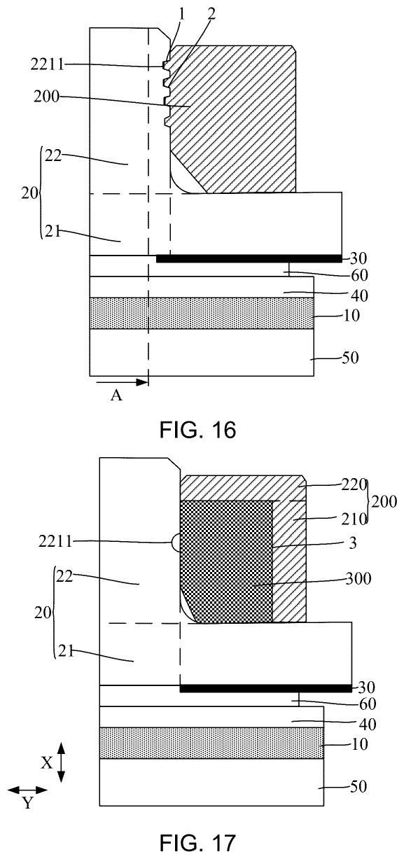

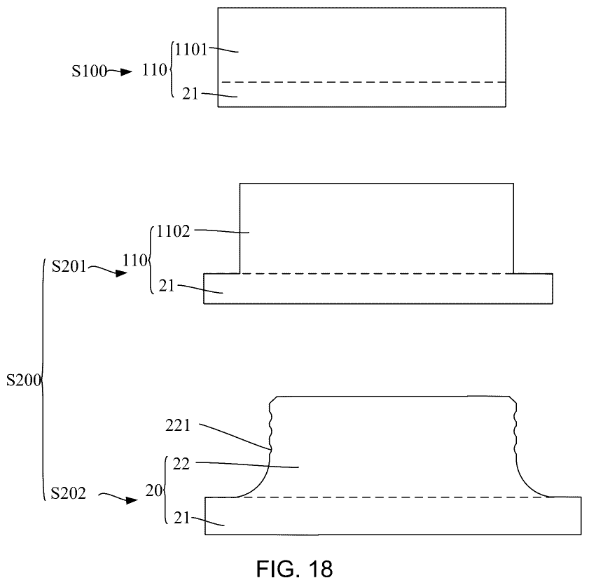

In some embodiments, as shown in FIGS. 16 and 17, the display apparatus 1000 further includes a middle frame 200. The middle frame 200 is located on the side of the first sub-portion 21 of the cover plate 20 away from the display panel 10. The middle frame 200 extends along the circumferential direction of the second sub-portion 22 of the cover plate 20 and surrounds the first sub-portion 21.

In this way, in the case of a collision between the display apparatus 1000 and an external object, the middle frame 200 will collide with the external object first, thereby ameliorating the problem of damage to the cover plate 20 caused by the collision between the display apparatus 1000 and the external object.

As shown in FIGS. 16 and 17, the middle frame 200 wraps at least a portion of the concave-convex structure 221 of the second sub-portion 22.

In this way, in the case of a collision between the display apparatus 1000 and an external object, the middle frame 200 will collide with the external object first, so that the middle frame 200 may mitigate the problem of damage to the concave-convex structure 221 caused by the collision between the display apparatus 1000 and the external object.

Two connection methods of the middle frame 200 and the cover plate 20 will be introduced below.

In some embodiments, as shown in FIG. 16, the orthographic projection of the sidewall of the second sub-portion 22 on the display panel 10 is substantially in a shape of a circle. The groove 2211 extends along the circumferential direction of the second sub-portion 22. Two extending ends of the groove 2211 are a first end and a second end, and the second end is located on a side of the first end close to the first sub-portion 21, so as to form a first thread 1. A sidewall of the middle frame 200 close to the second sub-portion 22 is provided with a second thread 2. The first thread 1 and the second thread 2 are screwed together. The term “substantially in a shape of a circle” means in a shape of a circle as a whole, but is not limited to a shape of a standard circle. That is, the “circle” here includes not only a standard circle but also a shape similar to a circle.

In this way, the cover plate 20 and the middle frame 200 may be mounted and removed conveniently.

In some examples, as shown in FIG. 16, the groove 2211 surrounds the second sub-portion 22 at least three turns.

For example, the groove 2211 surrounds the second sub-portion 22 for three, four, four and a half, five, or six turns, which will not be listed one by one in the embodiments of the present disclosure.

In this way, the first thread 1 and the second thread 2 are screwed together for a large number of turns, so that the cover plate 20 and the middle frame 200 may be connected firmly.

In some examples, as shown in FIG. 16, when the middle frame 200 and the cover plate 20 are connected by threads (the first thread 1 and the second thread 2), the middle frame 200 is further in contact with the first sub-portion 21.

In this way, the first sub-portion 21 supports the middle frame 200, which may mitigate the problem of the first thread 1 and the second thread 2 being squeezed against each other due to the gravity of the middle frame 200, and reduce the risk of a fast thread wear caused by the first thread 1 and the second thread 2 being squeezed against each other.

In some other embodiments, as shown in FIG. 17, the middle frame 200 and the cover plate 20 enclose an accommodation cavity 3. The display apparatus 1000 further includes a bonding block 300. The bonding block 300 is located inside the accommodation cavity 3. The middle frame 200 and the cover plate 20 are bonded through the bonding block 300.

In this way, the groove 2211 and the middle frame 200 will not be squeezed against each other, thus reducing the risk of the groove 2211 being damaged due to the squeeze between the groove 2211 and the middle frame 200.

For example, as shown in FIG. 17, the middle frame 200 includes a first extension portion 210 and a second extension portion 220. The first extension portion 210 extends in the first direction X, and has a spacing from the second sub-portion 22. The second extension portion 220 extends in the second direction Y, and has a spacing from the first sub-portion 21. An end of the second extension portion 220 away from the second sub-portion 22 is connected to an end of the second extension portion 220 away from the first sub-portion 21. The second direction Y and the first direction X intersect. For example, the second direction Y is perpendicular to the first direction X. The first extension portion 210, the second extension portion 220, the second sub-portion 22 and the first sub-portion 21 enclose the accommodation cavity 3. The first extension portion 210 and the second sub-portion 22 are bonded together through the bonding block 300, and the second extension portion 220 and the first sub-portion 21 are bonded together through the bonding block 300.

In some embodiments, as shown in FIGS. 16 and 17, the display module 100 further includes a light-shielding layer 30. The light-shielding layer 30 is located between the display panel 10 and the cover plate 20, and surrounds the display region A. An orthographic projection of the light-shielding layer 30 on the display panel 10 at least partially overlaps with an orthographic projection, on the display panel 10, of a portion of the first sub-portion 21 exceeding the second sub-portion 22.

For example, as shown in FIG. 16, the orthographic projection of the light-shielding layer 30 on the display panel 10 partially overlaps with the orthographic projection of the second sub-portion 22 on the display panel 10.

As shown in FIGS. 16 and 17, the display module 100 further includes a circular polarizer 40, a back film 50 and a first adhesive layer 60.

The circular polarizer 40 is located between the light-shielding layer 30 and the display panel 10. The first adhesive layer 60 is located between the light-shielding layer 30 and the circular polarizer 40. The cover plate 20 and the circular polarizer 40 are bonded together through the first adhesive layer 60. The back film 50 is located on a side of the display panel 10 away from the cover plate 20.

Some embodiments of the present disclosure further provide a method of manufacturing a cover plate 20, and as shown in FIG. 18, the method of manufacturing the cover plate 20 includes S100 to S400.

In S100, an initial cover plate 110 is provided.

The initial cover plate 110 includes a first initial second sub-portion 1101 and a first sub-portion 21 that are stacked.

For example, a ratio of a thickness of the first initial second sub-portion 1101 to a thickness of the first sub-portion 21 is 3.

In S200, an edge portion of the first initial second sub-portion 1101 is removed to form a second sub-portion 22.

For example, S200 includes S201 to S202.

In S201, a part of the first initial second sub-portion 1101 is removed to form a second initial second sub-portion 1102.

A boundary of the second initial second sub-portion 1102 is located within a boundary of the first sub-portion 21, and has a spacing from the boundary of the first sub-portion 21.

For example, the first initial second sub-portion 1101 is processsed by using a computer numerical control (CNC) machine tool to form the second initial second sub-portion 1102. During the process, a processing allowance of the CNC machine tool may be relatively large. For example, the processing allowance is in a range of 2 mm to 3 mm.

For example, the processing allowance is 2 mm, 2.1 mm, 2.2 mm, 2.3 mm, 2.4 mm, 2.7 mm, 2.8 mm, 2.9 mm or 3 mm, which will not be listed one by one in the embodiments of the present disclosure.

In this way, the processing speed of the CNC machine tool is higher, thereby reducing the manufacturing time of the cover plate 20.

In S202, a part of the second initial second sub-portion 1102 is removed to form a second sub-portion 22, so as to form the cover plate 20.

A boundary of the second sub-portion 22 is located within the boundary of the first sub-portion 21 and has a spacing from the boundary of the first sub-portion 21. A sidewall of the second sub-portion 22 is provided with a concave-convex structure 221. The concave-convex structure 221 extends along the circumferential direction of the second sub-portion 22 and surrounds at least a portion of the second sub-portion 22.

For example, the second initial second sub-portion 1102 may be processed by using a CNC machine tool to form the second sub-portion 22. During the process, a processing allowance of the CNC machine tool may be relatively small. For example, the processing allowance is less than 1 mm.

For example, the processing allowance is 100 μm, 150 μm, 300 μm, 500 μm, 700 μm, 800 μm, 850 μm, 950 μm or 1 mm, which will not be listed one by one in the embodiments of the present disclosure.

In this way, the CNC machine tool may process at a lower speed, thereby improving the surface quality of the concave-convex structure.

In S300, the sidewall of the second sub-portion 22 and a surface of the concave-convex structure 221 may be polished.

For example, the sidewall of the second sub-portion 22 and a surface of the concave-convex structure 221 may be polished by using a polishing machine, so that the surface roughness of the sidewall of the second sub-portion 22 is less than 10 nm.

In this way, the sidewall of the second sub-portion 22 may be smooth. That is, the sidewall of the second sub-portion 22 has good quality, thereby improving the mechanical properties of the sidewall of the second sub-portion 22, and in turn improving the mechanical properties of the display apparatus 1000.

In S400, the cover plate 20 undergoes coating, silk-screening, cleaning, and testing processes.

In the description of the specification, specific features, structures, materials or characteristics may be combined in a suitable manner in any one or more embodiments or examples.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display module, comprising:
a display panel having a display region; and
a cover plate located on a display side of the display panel, wherein the cover plate includes a first sub-portion and a second sub-portion; an orthographic projection of the first sub-portion on the display panel covers the display region, and a boundary of the orthographic projection of the first sub-portion on the display panel and a boundary of the display region are spaced apart; the second sub-portion is located on a side of the first sub-portion away from the display panel; a boundary of an orthographic projection of the second sub-portion on the display panel is located within the boundary of the orthographic projection of the first sub-portion on the display panel, and the boundary of the orthographic projection of the second sub-portion on the display panel and the boundary of the display region are spaced apart;
wherein a sidewall of the second sub-portion is provided with a concave-convex structure, and the concave-convex structure extends along a circumferential direction of the second sub-portion and surrounds at least a portion of the second sub-portion.

2. The display module according to claim 1, wherein a surface roughness of the sidewall of the second sub-portion is less than or equal to 10 nm.

3. The display module according to claim 1, wherein the concave-convex structure includes a plurality of grooves arranged in a first direction, and the plurality of grooves are arranged continuously and/or at intervals, the first direction being perpendicular to the cover plate.

4. The display module according to claim 3, wherein a maximum depth of a groove is greater than a distance between two adjacent grooves.

5. The display module according to claim 1, wherein the concave-convex structure includes one groove and/or one protrusion.

6. The display module according to claim 1, wherein a distance between an end of the concave-convex structure away from the first sub-portion and the first sub-portion is greater than a half of a thickness of the second sub-portion.

7. The display module according to claim 6, wherein a distance between an end of the concave-convex structure close to the first sub-portion and the first sub-portion is less than or equal to a half of the thickness of the second sub-portion.

8. The display module according to claim 1, wherein an edge of a surface of the second sub-portion away from the first sub-portion is provided with a chamfer; and a ratio of a distance between an end of the concave-convex structure away from the first sub-portion and a surface of the second sub-portion away from the first sub-portion to a thickness of the second sub-portion is in a range of 0.05 to 0.2.

9. The display module according to claim 1, wherein an orthographic projection of the sidewall of the second sub-portion on the display panel is substantially in a shape of a circle.

10. The display module according to claim 9, wherein the concave-convex structure includes a groove, and the groove extends along a circumferential direction of the second sub-portion; two extending ends of the groove are a first end and a second end; and the second end is located on a side of the first end close to the first sub-portion to form a first thread.

11. The display module according to claim 10, wherein the groove surrounds the second sub-portion at least three turns.

12. The display module according to claim 1, wherein a boundary line of an orthographic projection of the concave-convex structure on a reference plane includes a curved line and a straight line, the reference plane being perpendicular to the cover plate and perpendicular to a boundary of the second sub-portion.

13. The display module according to claim 1, wherein the concave-convex structure of the second sub-portion of the cover plate includes a groove, and a ratio of a maximum depth of the groove to a distance between a boundary of the display region of the display panel and a boundary of an orthographic projection of the sidewall of the second sub-portion on the display panel is in a range of 0.05 to 1.

14. The display module according to claim 1, wherein a distance between a boundary of the display region of the display panel and a boundary of an orthographic projection of the sidewall of the second sub-portion on the display panel is in a range of 150 μm to 300 μm.

15. A display apparatus, comprising:
the display module according to claim 1;
a middle frame located on the side of the first sub-portion of the cover plate away from the display panel, wherein the middle frame extends along the circumferential direction of the second sub-portion of the cover plate and surrounds the first sub-portion; and the middle frame wraps at least a portion of the concave-convex structure of the second sub-portion.

16. The display apparatus according to claim 15, wherein the concave-convex structure includes a groove, and the groove extends along a circumferential direction of the second sub-portion; two extending ends of the groove are a first end and a second end; the second end is located on a side of the first end close to the first sub-portion to form a first thread, a sidewall of the middle frame close to the second sub-portion is provided with a second thread, and the first thread and the second thread are screwed together.

17. The display apparatus according to claim 15, wherein the middle frame and the cover plate enclose an accommodation cavity; the display apparatus further comprises a bonding block, the bonding block is located inside the accommodation cavity, and the middle frame and the cover plate are bonded through the bonding block.

18. The display apparatus according to claim 15, wherein the display module further includes:
a light-shielding layer located between the display panel and the cover plate and surrounding the display region of the display panel, wherein an orthographic projection of the light-shielding layer on the display panel at least partially overlaps with an orthographic projection, on the display panel, of a portion of the first sub-portion exceeding the second sub-portion.

19. The display apparatus according to claim 18, wherein the orthographic projection of the light-shielding layer on the display panel partially overlaps with the orthographic projection of the second sub-portion on the display panel.

20. The display module according to claim 2, wherein the concave-convex structure includes a plurality of grooves arranged in a first direction, and the plurality of grooves are arranged continuously and/or at intervals, the first direction being perpendicular to the cover plate.
